(19) United States
(12) Patent Application Publication
(10) Pub. No.: US 2023/0335664 A1
(43) Pub. Date: Oct. 19, 2023

(54) Cascaded Avalanche Photodiode with High Responsivity and High Saturation Current

(71) Applicant: National Central University, Taoyuan City (TW)

(72) Inventor: Jin-Wei Shi, Taoyuan City (TW)

(21) Appl. No.: 17/976,966

(22) Filed: Oct. 31, 2022

Related U.S. Application Data
(60) Provisional application No. 63/331,952, filed on Apr. 18, 2022.

(51) Int. Cl. H01L 31/107; H01L 31/0304; H01L 31/0352; G01S 7/481

(52) U.S. Cl. CPC H01L 31/1075; H01L 31/03046; H01L 31/03529; G01S 7/4816; H04B 10/691

(57) ABSTRACT

A cascaded avalanche photodiode (APD) is provided with high responsivity and high saturation current. Single multiplication layer (M-layer) is inserted with multiple field control layers to be cut into several M-layers in different regions. Thus, with the breakdown voltage decreased, the critical field lowered, the saturation power enhanced, and the gain increased, avalanche breakdown effect is achieved.

### TECHNICAL FIELD OF THE INVENTION

The present invention relates to cascaded avalanche photodiode (APD) with high responsivity and high saturation current; more particularly, to inserting multiple field control layers to a single multiplication (M-) layer to be cut into a plurality of M-layers located separately in different regions, where, with a breakdown voltage decreased, a critical field lowered, a saturation power enhanced, and a gain increased, avalanche breakdown effect is achieved.

### DESCRIPTION OF THE RELATED ARTS

For decades, avalanche photodiodes (APDs) have played an important role at receiving ends of many different applications such as optical fiber communications, biosensing, lidars, quantum optics, quantum computing, and wireless optical communications. As compared with other semiconductor photodetectors (including phototransistors and photoconductors) having large internal gains, the APDs generally have better performances like shorter internal response time, wider optical-to-electrical (O-E) bandwidth, lower noise-equivalent-power (NEP), higher sensitivity, etc. On the other hand, the high gain of the APD comes at the cost of its lower output saturation current density and smaller O-E bandwidth as compared to a p-i-n PD counterpart having unity gain, which is due to the extra carrier multiplication process within active layer.

Recently, optical receivers having large dynamic range are used in analog systems in great demand. An important issue of application is to maintain high responsiveness and high-speed performance of APD devices at high saturation output currents. Taking a coherent receiver in a frequency modulated continuous wave (FMCW) lidar as an example, a highly linear p-i-n PD can provide high saturated RF output power under intense power pumping by an optical local oscillator (LO), which is very suitable for amplifying a weak received light. However, significant optical insertion loss remains to be a challenge in FMCW lidar systems based on advanced photonic integrated circuit (PIC), which results in limited output optical LO power (several mW).

In conventional APDs with high responsivity, the saturation currents are usually limited by space-charge screening (SCS) effects in thicker indium gallium arsenide (In_{0.53}Ga_{0.47}As) absorber layers (˜2 μm). By reducing the doping density in the charge layer, a stronger electric field can be distributed in the absorber layer to suppress this SCS effect. However, it will result in an increase in breakdown (operation) voltage (Vbr) and more severe device heat under high power operation.

There was a previously designed boss structure of APD, as shown in FIG. 8, which is hereinafter referred to as prior art. The prior art 8 comprised a p⁺-type In_{0.53}Ga_{0.47}As contact layer 31, an In_{0.52}Al_{0.48}As window layer 32, an intrinsic In_{0.53}Ga_{0.47}As absorption layer 33, two p-type In_{0.52}Al_{0.48}As electric field control layers 34, two intrinsic In_{0.52}Al_{0.48}As multiplication (M-) layers 35, and two N⁺-type In_{0.52}Al_{0.48}As/InP contact layers 36. Therein, two In_{0.52}AlₓGa_{0.48-}As graded bandgap layers 37 were respectively inserted into the interface between the absorption layer 33 and the window layer 32 and that between the absorption layer 33 and the M-layer 35.

However, the operating gain of the prior art would gradually decrease with the increase of the optical pump power. Hence, the prior art does not fulfill all users' requests on actual use.

### SUMMARY OF THE INVENTION

The main purpose of the present invention is to fundamentally overcome the trade-off between responsivity and saturation current of APD in FMCW (frequency modulated continuous wave) IiDAR and high-speed optical communication application.

To achieve the above purposes, the present invention is a cascaded avalanche photodiode (APD) with high responsivity and high saturation current, where a single M-layer is inserted with multiple field control layers to be cut into a plurality of M-layers located separately in different regions for, with a breakdown voltage decreased, a critical field lowered, a saturation power enhanced, and a gain increased, achieving avalanche breakdown effect;
and where the APD comprises a P-type contact layer, being a first semiconductor of doped p⁺-doped; two N-type contact layers, being a second and a third semiconductors of n⁺/n-doped; a P-type window layer, being a fourth semiconductor of p⁺-doped to be interposed between said p-type ohmic contact layer and said DBR layer; a first graded bandgap layer, being a fifth semiconductor of p⁺-doped to be interposed between said P-type window layer and said two N-type contact layers; an absorption layer, being a sixth semiconductor of undoped to be interposed between said first graded bandgap layer and said two N-type contact layers; a second graded bandgap layer, being a seventh semiconductor of undoped to be interposed between said absorption layer and said two N-type contact layers; a first P-type field control layer, being an eighth semiconductor of p-doped to be interposed between said second graded bandgap layer and said two N-type contact layers; a second P-type field control layer, being a ninth semiconductor of p-doped to be interposed between said first P-type field control layer and said two N-type contact layers; a first M-layer, being a tenth semiconductor of undoped to be interposed between said second P-type field control layer and said two N-type contact layers; a third P-type field control layer, being an eleventh semiconductor of p-doped to be interposed between said first M-layer and said two N-type contact layer; a second M-layer, being a twelfth semiconductor of undoped to be interposed between said third P-type field control layer and said two N-type contact layers; a fourth P-type field control layer, being a thirteenth semiconductor of p-doped to be interposed between said second M-layer and said two N-type contact layer; and a third M-layer, being a fourteenth semiconductor of undoped to be interposed between said fourth P-type field control layer and said two N-type contact layers, where the APD has a from-top-to-bottom structure, comprising said P-type contact layer, said P-type window layer, said first graded bandgap layer, said absorption layer, said first graded bandgap layer, said first P-type field control layer, said second P-type field control layer, said first M-layer, said second P-type field control layer, said second M-layer, said fourth P-type field control layer, said third M-layer, said N-type contact layer, and said N-type contact layer, to obtain an epitaxial-layers structure with an n-side (M-layer) down electrode; and wherein, with a continuous stacking and multiplying multi-layer having at least three layers while inserting an electric field control layer above each M-layer, the trade-off between responsivity and saturation current in APD is performed.

### BRIEF DESCRIPTION OF THE DRAWINGS

The present invention will be better understood from the following detailed description of the preferred embodiment according to the present invention, taken in conjunction with the accompanying drawings, in which

FIG. 1 is the cross-sectional view showing the first preferred embodiment of the APD according to the present invention;

FIG. 2 is the view showing the calculated electric fields along the AA′ and BB′ directions in FIG. 1 at the punch-through and breakdown voltages of the first preferred embodiment;

FIG. 3 is the view showing the calculated electric fields along the AA′ and BB′ directions in FIG. 1 at the punch-through and breakdown voltages of the prior art;

FIG. 4 is the view showing the measured bias-dependent dark currents, photocurrents, and operation gains of the first and the second preferred embodiments and the prior art, respectively, subjected to different optical pumping powers;

FIG. 5 is the view showing the relationships between the direct current (DC) output photocurrents and the input optical powers measured from the first and the second preferred embodiments and the prior art;

FIG. 6 is the view showing the relationships between the DC output photocurrents and the input optical powers of the second preferred embodiment and the prior art under different bias voltages;

FIG. 7 is the view showing the dark currents, photocurrents, operation gains, O-E frequency responses, and OUTs (K, F, and C) captured by the first and the second preferred embodiments as receivers; and

FIG. 8 is the cross-sectional view of the prior art.

### DESCRIPTION OF THE PREFERRED EMBODIMENT

The following description of the preferred embodiment is provided to understand the features and the structures of the present invention.

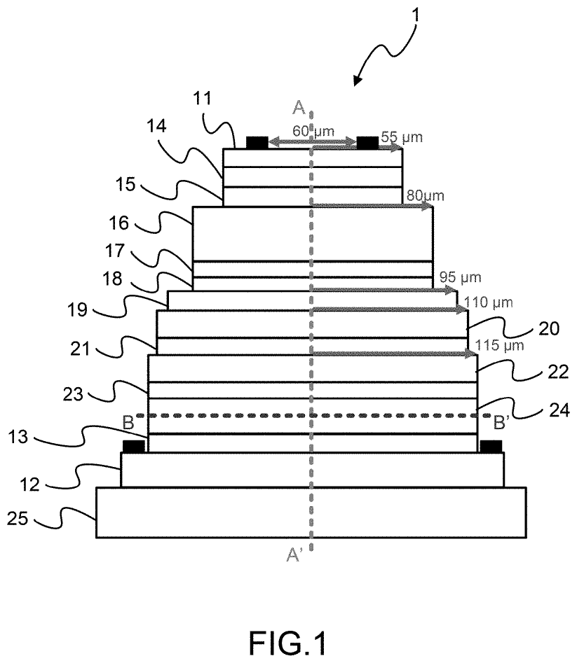

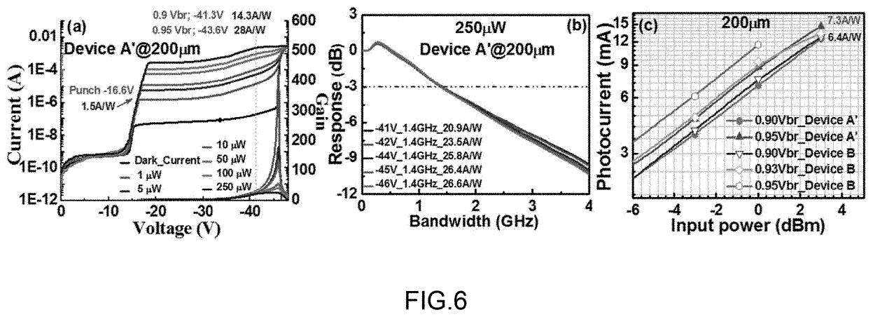

Please refer to FIG. 1 to FIG. 8, which are a cross-sectional view showing a first preferred embodiment of an APD according to the present invention; a view showing calculated electric fields along AA′ and BB′ directions in FIG. 1 at punch-through and breakdown voltages of the first preferred embodiment; a view showing calculated electric fields along AA′ and BB′ directions in FIG. 1 at punch-through and breakdown voltages of a prior art; a view showing measured bias-dependent dark currents, photocurrents, and operation gains of the first and a second preferred embodiments and the prior art, respectively, subjected to different optical pumping powers; a view showing relationships between direct current (DC) output photocurrents and input optical powers measured from the first and the second preferred embodiments and the prior art; a view showing relationships between DC output photocurrents and input optical powers of the second preferred embodiment and the prior art under different bias voltages; and a view showing dark currents, photocurrents, operation gains, O-E frequency responses, and OUTs (K, F, and C) captured by the first and the second preferred embodiments as receivers. As shown in the figures, the present invention is a cascaded APD with high responsivity and high saturation current, comprising a P-type contact layer 11, two N-type contact layers 12,13, a P-type window layer 14, a first graded bandgap layer 15, an absorption layer 16, a second graded bandgap layer 17, a first P-type field control layer 18, a second P-type field control layer 19, a first multiplication (M-) layer 20, a third P-type field control layer 21, a second M-layer 22, a fourth P-type field control layer 23, and a third M-layer 24, to form an epitaxial-layers structure grown on a semi-insulating semiconductor substrate or a conductive semiconductor substrate 25. Thus, a novel cascaded APD with high responsivity and high saturation current is obtained.

In a first preferred embodiment 1, the APD is fit to be used in a frequency modulated continuous wave (FMCW) lidar, whose structure is the same as that shown in FIG. 1. The first preferred embodiment 1 has a from-top-to-bottom structure, comprising a p⁺-type indium gallium arsenide (In_{0.53}Ga_{0.47}As) contact layer with a thickness of 120 nanometers (nm); an indium phosphide (InP) window layer with a thickness of 500 nm; a p-type indium aluminum gallium arsenide (InAlGaAs) graded bandgap layer with a thickness of 40 nm; an undoped In_{0.53}Ga_{0.47}As absorption layer with a thickness of 2000 nm; an undoped InGaAs or InAlAs graded bandgap layer with a thickness of 30 nm; three p-type In_{0.52}Al_{0.48}As electric field control layers and a p-type InP electric field control layer with thicknesses of 30 nm, 30 nm, 30 nm, and 120 nm; three undoped In_{0.52}Al_{0.48}As M-layers with thicknesses of 100 nm, 100 nm and 400 nm; and two N⁺-type In_{0.52}Al_{0.48}As/InP contact layers. An epitaxial-layers structure with an n-side (M-layer) down electrode is thus obtained, where, with a continuous stacking and multiplying multi-layer having at least three layers while inserting an electric field control layer above each M-layer, the trade-off between responsivity and saturation current of APD is fundamentally overcome to be applied in a receiver of FMCW (frequency modulated continuous wave) LiDAR and high-speed optical communication system.

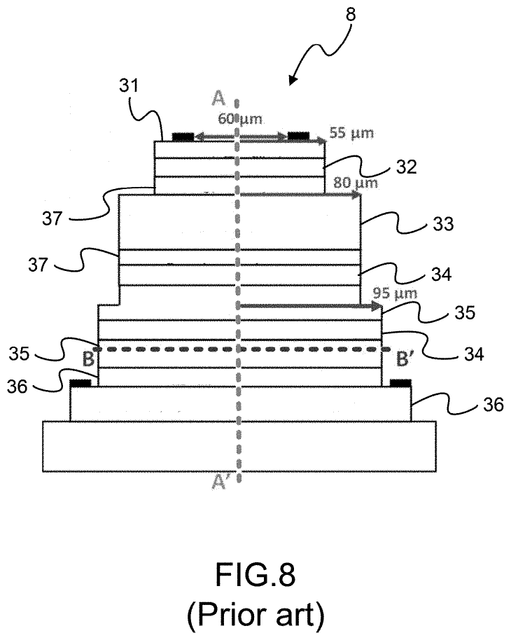

The thickness of each of epitaxial layer is clearly described in the above. The first preferred embodiment 1 and a prior art 8 (as shown in FIG. 8) have the same thickness of 2 microns (μm) for the In_{0.53}Ga_{0.47}As absorber layers and the thicknesses of their M-layers are similar (600 vs. 500 nm, respectively). In the present invention, a single M-layer is inserted with a plurality of electric field control layers to be cut into a plurality of M-layers located separately in different regions. As taking the first preferred embodiment 1 as an example, the above-mentioned 600-nm-thick M-layer is subdivided into three parts: the first M-layer 20 of 100 nm, the second M-layer 22 of 100 nm, and the third M-layer 24 of 400 nm. Thus, with a breakdown voltage decreased, a critical field lowered, a saturation power enhanced, and a gain increased, an effect of avalanche breakdown is achieved.

Accordingly, owing to the stepped electric field distributions in the multiplication regions, electrons are excited in the first and second M-layers 20, 22. Furthermore, because the electric field strength is insufficient, significant impact ionization may not be triggered. Finally, the electrons are transferred to the third M-layer 24, which is closely connected with the N-type contact layer 13, and a process of continuous impact ionization is started. Hence, the present invention proposes a design of M-layers to provide better impact ionization localization than that of a single uniformly-thick build-up layer; and, thus, the delay time caused by the avalanche in APD can be significantly reduced.

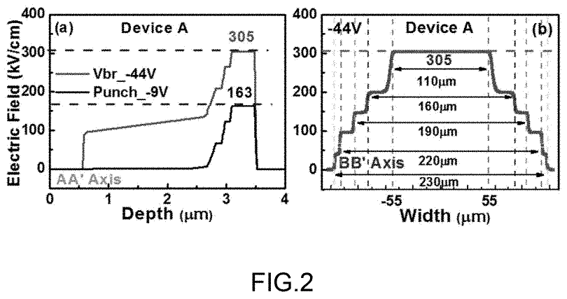

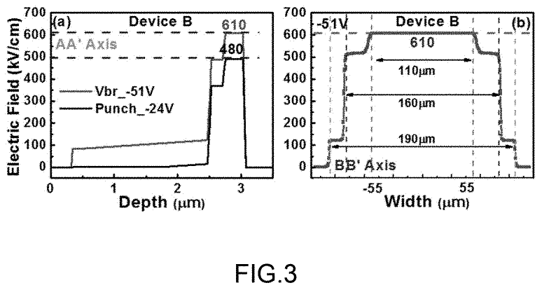

FIG. 2 and FIG. 3 show the calculated electric field distributions along the vertical (AA′) and horizontal (BB′) directions shown in FIG. 1 under punch-through/breakdown voltages of the first preferred embodiment 1 and the prior art 8, respectively. As results show, FIG. 2 shows a one-dimensional electric field simulated by the first preferred embodiment 1, where the critical electric field of multiplication region can be reduced to 305 kilovolts per centimeter (kV/cm) with a breakdown voltage of −44 volts (V); and FIG. 3 shows a one-dimensional electric field simulated by the prior art 8, where the critical electric field of multiplication region is 610 kV/cm with a breakdown voltage of −51 V. For designing the structure of APD, a lower critical electric field means a smaller operation voltage (Vbr), a lower device heating, and a strong electric field distributed in the thicker In_{0.53}Ga_{0.47}As absorption layer for suppressing space-charge screening (SCS) effect and thereby obtaining a higher saturation output photocurrent density. Overall, the design of multiple M-layers in the present invention can fundamentally relax the limitation of high-gain APD on saturation for providing shorter avalanche delay time and greater gain-bandwidth product (GBP) than the conventional APD designs having the same M-layer thickness.

As seen in FIG. 2 and FIG. 3, the electric field for avalanche breakdown of the first preferred embodiment 1 is only 305 kV/cm, where the prior art 8 needs as high as 610 kV/cm for the breakdown; and the first preferred embodiment 1 can effectively reduce breakdown electric field, which is reduced from −51 V to −44 V. In another word, the first preferred embodiment 1 can lower the electric field of M-layer and raise the electric field of absorber layer while maintaining the breakdown phenomenon at the same time. Therefore, the present invention can use a smaller breakdown voltage (−51 V down to −44 V) and a lower critical electric field to achieve avalanche breakdown effect.

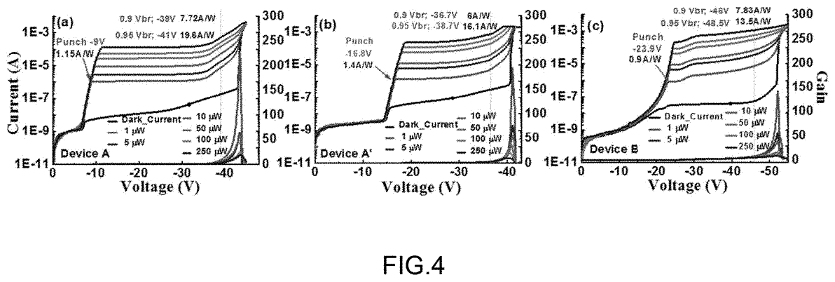

FIG. 4 shows measured dark currents, photocurrents and operation gains versus bias voltage for (a) the first preferred embodiment 1, (b) a second preferred embodiment, and (c) the prior art 8 subjected to different optical pump powers at 1.55 μm optical wavelength, separately. Therein, the second preferred embodiment has exactly the same epitaxial-layers structure as the first preferred embodiment 1 with a doping density of electric-field control layer tuned to obtain a larger reverse bias punch through voltage (Vpt) (−16 V vs. −9 V). As results show, the measured breakdown voltages (Vbr) of the first preferred embodiment 1, the second preferred embodiment, and the prior art 8 are about −41 V, −39 V, and −49 V, respectively, which proves that the first preferred embodiment 1 simultaneously reduce Vpt and Vbr as well. Thus, the lowered punch point means a higher electric field of absorber layer and a better high-power performance.

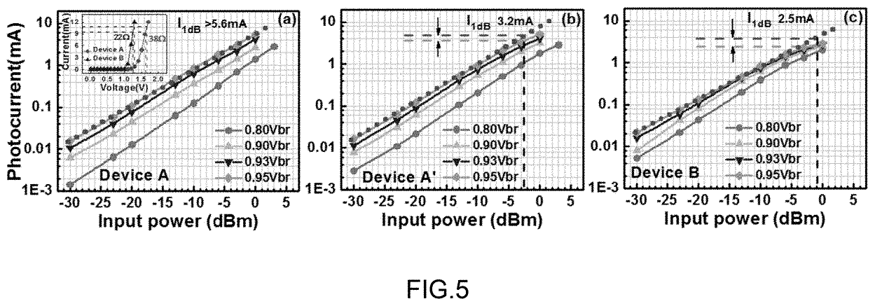

FIG. 5 shows the relationship between direct output photocurrents and input optical powers measured for (a) the first preferred embodiment 1, (b) the second preferred embodiment, and (c) the prior art 8 with the same active window diameter of 60 μm, separately, where the inset in diagram (a) shows the measured forward bias I-V curves for the first preferred embodiment 1 and the prior art 8. As results show, diagram (a) shows that the photocurrent of the first preferred embodiment 1 is not easily saturated; and diagram (c) shows that the saturation photocurrent of the prior art 8 is smaller, which is easily saturated because of the smaller electric field of absorbing layer. As shown in diagram (a), the first preferred embodiment 1 is not saturated on exceeding 5.6 mA, yet the prior art 8 is saturated at 2.5 mA. Hence, as compared with the second preferred embodiment (I_{1 dB}: 3.2 mA) and the prior art 8 (I_{1 dB}: 2.5 mA), the first preferred embodiment 1 has a higher saturation current of 1 dB (I_{1 dB}: >5.6 mA).

In diagram (c) in FIG. 5, it shows the relationship between direct output photocurrents and input optical powers measured for the second preferred embodiment and the prior art 8 with the same active window diameter of 200 μm under different bias voltages, separately. As results show, when the first preferred embodiment 1 enlarges the area, the current can be very large. Because the second preferred embodiment has a smaller breakdown voltage, the heat is relatively small for withstanding a high current with a relatively high electric field of absorber layer. On the other hand, the breakdown voltage of the prior art 8 is very large and cannot withstand high current.

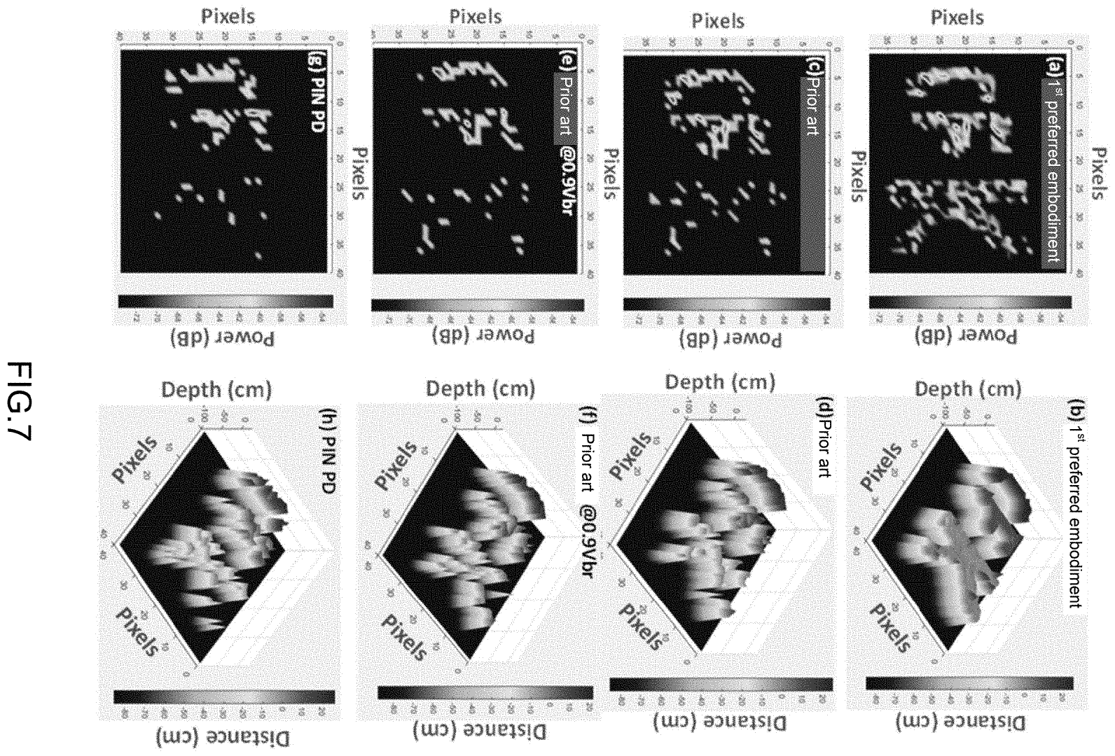

Diagram (a)˜(h) in FIG. 7 show the images of OUTs (K, F and C), which are captured by using the first preferred embodiment 1, the second preferred embodiment, and a PIN PD module as receivers, separately, and constructed based on each pixel with the downscaled intermediate frequency (IF) and power. Therein, diagram (a), (c), (e), and (g) are based on the IF power per pixel of the lidar images measured at 0.9 Vbr for the first preferred embodiment 1, 0.8 Vbr for the second preferred embodiment, 0.9 Vbr for the prior art 8, and for the PIN PD; and diagram (b), (d), (f), and (h) are based on the depth and distance information of each pixel in the 3D images captured at 0.9 Vbr for the first preferred embodiment 1, 0.8 Vbr for the second preferred embodiment, 0.9 Vbr for the prior art 8, and for the PIN PD. On being applied to a lidar receiver, it is found that the development effect of the first preferred embodiment 1 is obviously better, where a little optical power (0.5 mW) only is able to obtain a good image effect. Yet, the prior art 8 requires an optical power of 4 mW whether it is a none M-layer or a double-layered M-layer, whose effect is even worse than that of the first preferred embodiment 1.

The present invention proposes a novel APD design, which fundamentally overcomes the trade-off between responsivity and saturation current in FMCW IiDAR and high-speed optical communication applications of APD. By using multiple In_{0.52}Al_{0.48}As-based M-layers with stepped electric fields inside, the avalanche process in the multiple M-layers is more obvious than that in the double-layered M-layers so that the critical electric field is effectively reduced. Hence, the present invention distributes a stronger electric field in a thick absorption layer of APD with a smaller working voltage for reducing SCS effect and device heat at a high output photocurrent. As compared with the double-layered M-layer of the prior art 8 having the same active window size (60 μm), the first preferred embodiment 1 has an APD with a similar absorption performance and a similar M-layer thickness operated under 0.95 Vbr, which exhibits smaller Vpt and Vbr; higher responsivity (19.6 vs. 13.5 A/W); higher maximum gain (230 vs. 130); and higher 1-dB saturation current (>5.6 vs. 2.5 mA). Besides, when the diameter of the active window is further increased to 200 μm and the output current density is lowered, the first preferred embodiment 1 has a working voltage (Vbr) lowered and heats up less while maintaining better saturation current performance than the prior art 8 (>14.6 vs. 12.8 mA). On a self-heterodyne FMCW lidar test bench, this novel APD exhibits a greater signal-to-noise ratio per pixel and the quality of the constructed 3D image is better than that obtained by the double-layered M-layers of the prior art 8 and the high-performance commercial PIN PD module while less optical power (0.5 vs. 4 mW) is required. The above results prove that the novel APD according to the present invention further improves the sensitivity of next-generation FMCW lidar and high-speed optical communication system.

To sum up, the present invention is a cascaded APD with high responsivity and high saturation current, where a single M-layer is inserted with multiple field control layers to be cut into a plurality of M-layers located separately in different regions for, with a breakdown voltage decreased, a critical field lowered, a saturation power enhanced, and a gain increased, achieving avalanche breakdown effect.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A cascaded avalanche photodiode (APD) with high responsivity and high saturation current, wherein single multiplication (M-) layer is inserted with multiple field control layers to be cut into a plurality of M-layers located separately in different regions to, with a breakdown voltage decreased, a critical field lowered, a saturation power enhanced, and a gain increased, achieve an effect of avalanche breakdown.

2. The APD according to claim 1, wherein the APD comprises
a P-type contact layer, being a first semiconductor of doped p⁺-doped;
two N-type contact layers, being a second and a third semiconductors of n⁺/n-doped;
a P-type window layer, being a fourth semiconductor of p⁺-doped to be interposed between said p-type ohmic contact layer and said DBR layer;
a first graded bandgap layer, being a fifth semiconductor of p⁺-doped to be interposed between said P-type window layer and said two N-type contact layers;
an absorption layer, being a sixth semiconductor of undoped to be interposed between said first graded bandgap layer and said two N-type contact layers;
a second graded bandgap layer, being a seventh semiconductor of undoped to be interposed between said absorption layer and said two N-type contact layers;
a first P-type field control layer, being an eighth semiconductor of p-doped to be interposed between said second graded bandgap layer and said two N-type contact layers;
a second P-type field control layer, being a ninth semiconductor of p-doped to be interposed between said first P-type field control layer and said two N-type contact layers;
a first M-layer, being a tenth semiconductor of undoped to be interposed between said second P-type field control layer and said two N-type contact layers;
a third P-type field control layer, being an eleventh semiconductor of p-doped to be interposed between said first M-layer and said two N-type contact layer;
a second M-layer, being a twelfth semiconductor of undoped to be interposed between said third P-type field control layer and said two N-type contact layers;
a fourth P-type field control layer, being a thirteenth semiconductor of p-doped to be interposed between said second M-layer and said two N-type contact layer; and
a third M-layer, being a fourteenth semiconductor of undoped to be interposed between said fourth P-type field control layer and said two N-type contact layers,
wherein the APD has a from-top-to-bottom structure, comprising said P-type contact layer, said P-type window layer, said first graded bandgap layer, said absorption layer, said first graded bandgap layer, said first P-type field control layer, said second P-type field control layer, said first M-layer, said second P-type field control layer, said second M-layer, said fourth P-type field control layer, said third M-layer, said N-type contact layer, and said N-type contact layer, to obtain an epitaxial-layers structure with an n-side (M-layer) down electrode; and wherein, with a continuous stacking and multiplying multi-layer having at least three layers while inserting an electric field control layer above each M-layer, the trade-off between responsivity and saturation current in APD is performed.

3. The APD according to claim 2, wherein said epitaxial-layers structure is grown on a semiconductor substrate selected from a group consisting of a semi-insulating semiconductor substrate and a conductive semiconductor substrate.

4. The APD according to claim 2, wherein wherein said P-type contact layer is of p⁺-type indium gallium arsenide (InGaAs); said P-type window layer is of p⁺-type indium phosphide (InP); said first graded bandgap layer is of p⁺-type indium aluminum gallium arsenide (InAlGaAs); said absorption layer is of undoped InGaAs; said second graded bandgap layer is of a material selected from a group consisting of undoped InGaAs and undoped InAlAs; said first P-type field control layer is of p-doped InAlAs; said second P-type field control layer is of p-doped InP; said first M-layer is of undoped InAlAs; said third P-type field control layer is of p-doped InAlAs; said second M-layer is of undoped InAlAs; said fourth P-type field control layer is of p-doped InAlAs; said third M-layer is of undoped InAlAs; and said two N-type contact layers are respectively n-doped InAlAs and n⁺-doped InP.

5. The APD according to claim 2, wherein said P-type contact layer is of p⁺-type InₓGa₁₋ₓAs and x is 0.53.

6. The APD according to claim 2, wherein said absorption layer is of undoped InₓGa₁₋ₓAs and x is 0.53.

7. The APD according to claim 2, wherein said first, said third, and said fourth P-type field control layers are of p-doped InₓAl₁₋ₓAs and x is 0.52.

8. The APD according to claim 2, wherein said first, said second, and said third M-layers are of undoped InₓAl₁₋ₓAs and x is 0.52.

9. The APD according to claim 2, wherein said N-type contact layer is of n-doped InₓAl₁₋ₓAs and x is 0.52.

10. The APD according to claim 1, wherein the APD is a receiver in a frequency modulated continuous wave (FMCW) lidar and a high-speed optical communication system.
